(19) United States
(12) Patent Application Publication
(10) Pub. No.: US 2009/0267509 A1
(43) Pub. Date: Oct. 29, 2009

(54) Led lighting system for direct form, fit, and function replacement of existing incandescent, halogen, mercury vapor, high pressure sodium and compact fluorscent systems

(76) Inventor: Troy R. Broitzman, Wayzata, MN (US)

Correspondence Address: Troy Richard Broitzman, 2195 Daniels St., PO Box 907, Long Lake, MN, 55356-0907, US

(21) Appl. No.: 12/386,447

(22) Filed: Apr. 17, 2009

Related U.S. Application Data
(60) Provisional application No. 61/125,550, filed on Apr. 25, 2008.

(51) Int. Cl. H01L 33/00

(52) U.S. Cl. 313/512

(57) ABSTRACT

A white light LED-based lighting system configured for direct form, fit, and function replacement of existing incandescent, halogen, mercury vapor, high pressure sodium, and compact fluorescent systems is provided. The white light LED-based lighting system comprises a group of solid state light emitting diodes, electronics to activate the light emitting diodes, and an encapsulating housing enclosing the light emitting diodes and the activating electronics.

### CROSS-REFERENCE TO RELATED APPLICATIONS

The present application claims the benefit of and priority to U.S. Provisional Application Ser. No. 61/125,550, filed Apr. 25, 2008 the entire content of which being incorporated herein by reference.

### FIELD OF THE INVENTION

The present invention is directed generally to lighting systems, and more particularly to a white light LED-based lighting system configured for direct form, fit, and function replacement of existing incandescent, halogen, mercury vapor, high pressure sodium and compact fluorescent systems.

### BACKGROUND

Energy conservation, in all its varied forms, has become a national priority of the United States as well as the rest of the world, from both the practical point of view of limited natural resources and recently as a security issue to reduce our dependence on foreign oil. A large proportion (some estimates are as high as one third) of the electricity used in residential homes in the United States each year goes to lighting. The percentage is much higher for businesses, street lights, amongst other varied items. Accordingly, there is an ongoing need to provide lighting, which is more energy efficient. It is well known that incandescent light bulbs are very energy inefficient light sources—about ninety percent of the electricity they consume is released as heat rather than light. This heat adds to the cooling load of a system during cooling season. In heating season the cost per BTU of heat that the lights give off is typically more expensive than the cost per BTU of the main heat source. The heat that is given off by the lighting also can cause “over shooting” of the desired temperature which waists energy and makes the space feel uncomfortable. Fluorescent light bulbs are more efficient than incandescent light bulbs (by a factor of about four) but are still quite inefficient as compared to solid state light emitters, such as light emitting diodes (LED's).

In addition, as compared to the normal lifetimes of solid state light emitters, incandescent light bulbs have relatively short lifetimes, i.e., typically in the range of 750 to 2000 hours. Fluorescent bulbs have longer lifetimes (e.g., 8,000 to 20,000 hours), but provide less favorable color reproduction. In dramatic comparison, the lifetime of light emitting diodes, for example, can generally be measured in decades (approximately 100,000 hrs or more).

One established method of comparing the output of different light generating sources has been coined color reproduction. Color reproduction is typically given numerical values using the so-called Color Rendering Index (CRI). CRI is a relative measurement of how the color rendition of an illumination system compares to that of a blackbody radiator, i.e., it is a relative measure of the shift in surface color of an object when lit by a particular lamp. The CRI equals 100 if a set of test colors being illuminated by an illumination system are the same as the results as being irradiated by a blackbody radiator. Daylight has the highest CRI (100), with incandescent bulbs being relatively close (about 95), and fluorescent lighting being less accurate (70 to 85). Certain types of specialized lighting have relatively low CRI's (e.g., mercury vapor or sodium, both as low as about 40 or even lower). Sodium lights are used, e.g., to light highways and surface streets. Driver response time, however, significantly decreases with lower CRI values (for any given brightness, legibility decreases with lower CRI).

A practical issue faced by conventional lighting systems is the need to periodically replace the lighting devices (e.g., light bulbs, etc.). Such issues are particularly pronounced where access is difficult (e.g., vaulted ceilings, bridges, high buildings, traffic tunnels) and/or where change-out costs are extremely high. The typical lifetime of conventional fixtures is about 20 years, corresponding to a light-producing device usage of at least about 44,000 hours (based on a typical usage of 6 hours per day for 20 years). In contrast light-producing device lifetimes are typically much shorter, thus creating the need for periodic change-outs. The potential number of residential homes that may be candidates for these periodic change-outs of the traditional incandescent lighting systems, including base fixtures and lamps themselves, may be extremely large and represent an attractive commercial enterprise. For example, in the United States alone new residential home construction has average approximately 1.5 million dwellings per year over the last 30 years running. Even neglecting older homes built before 1978, this represents at least 45 million residential dwellings that are candidates for potential upgrades to more energy efficient LED-based lighting systems.

Accordingly, for these and other reasons, efforts have been ongoing to develop ways by which solid state light emitters can be used in place of incandescent lights, fluorescent lights and other light-generating devices in a wide variety of applications. In addition, where solid state light emitters are already being used, efforts are ongoing to provide solid state light emitter-containing devices which are improved energy efficiency, color rendering index (CRI), contrast, and useful lifetime.

Light emitting diodes are well-known semiconductor devices that convert electrical current into light. A wide variety of light emitting diodes are used in increasingly diverse fields for an ever-expanding range of purposes. More specifically, light emitting diodes are semiconducting devices that emit light (ultraviolet, visible, or infrared) when an electrical potential difference is applied across a p-n junction structure. There are a number of well-known ways to make light emitting diodes and many associated structures, and the present invention can employ any such manufacturing technique.

The commonly recognized and commercially available light emitting diodes that are sold, for example, in electronics stores typically represents a “packaged” device made up of a number of parts. These packaged devices typically include a semiconductor-based light emitting diode and a means to encapsulate the light emitting diode. As is well known, a light emitting diode produces light by exciting electrons across the band gap between a conduction band and a valence band of a semiconductor active (light-emitting) layer. The electron transition generates light at a wavelength that depends on the band-gap energy difference. Thus, the color of the light (usually expressed in terms of its wavelength) emitted by a light emitting diode depends on the semiconductor materials of the active layers of the light emitting diode.

Although the development of solid state light emitters, e.g., light emitting diodes, has in many ways revolutionized the lighting industry, some of the characteristics of solid state light emitters have presented challenges, some of which have not yet been fully met. For example, the emission spectrum of any particular light emitting diode is typically concentrated around a single wavelength (as dictated by the light emitting diode's composition and structure), which is desirable for some applications, but not desirable for others, e.g., for providing lighting, given that such an emission spectrum typically provides a very low CRI.

Because light that is perceived as white is necessarily a blend of light of two or more colors (or wavelengths), no single light emitting diode can produce white light. “White light” emitting devices have been produced which have a light emitting diode structure comprising individual red, green and blue light emitting diodes mounted on a common substrate. Other “white light” emitting devices have been produced which include a light emitting diode which generates blue light and a luminescent material (e.g., a phosphor) that emits yellow light in response to excitation by the blue LED output, whereby the blue and the yellow light, when appropriately mixed, produce light that is perceived as white light. A wide variety of luminescent materials are well-known and available to persons of skill in the art. For example, a phosphor is a luminescent material that emits a responsive radiation (typically visible light) when excited by a source of exciting radiation. In many instances, the responsive radiation has a wavelength, which is different, typically longer, from the wavelength of the exciting radiation. Other examples of luminescent materials include day glow tapes and inks, which glow in the visible spectrum upon illumination with ultraviolet light. Luminescent materials can be categorized as being down-converting, i.e., a material which converts photons to a lower energy level (longer wavelength) or up-converting, i.e., a material which converts photons to a higher energy level (shorter wavelength). Inclusion of luminescent materials in LED devices has typically been accomplished by adding the luminescent materials to a clear plastic encapsulating material (e.g., epoxy-based or silicone-based material).

As noted above, “white LED lights” (i.e., lights which are perceived as being white or near-white) have been investigated as potential replacements for white light incandescent lamps. A representative example of a white LED lamp includes a package of a blue light emitting diode chip, made of gallium nitride (GaN), coated with a phosphor such as Yttrium Aluminum Garnet (YAG). In such an LED lamp, the blue light emitting diode chip produces a blue emission and the phosphor produces yellow fluorescence on adsorbing that emission. For instance, in some designs, white light emitting diodes are fabricated by forming a ceramic phosphor layer on the output surface of a blue light-emitting semiconductor light emitting diode. Part of the blue rays emitted from the light emitting diode pass through the phosphor, while part of the blue rays emitted from the light emitting diode chip are absorbed by the phosphor, which becomes excited and emits a yellow ray. The part of the blue light emitted by the light emitting diode, which is transmitted through the phosphor, is mixed with the yellow light emitted by the phosphor. The viewer perceives the mixture of blue and yellow light as white light.

In another type of LED lamp, a light emitting diode chip that emits an ultraviolet ray is combined with phosphor materials that produce red (R), green (G) and blue (B) light rays. In such an “RGB LED lamp”, the ultraviolet rays that have been radiated from the light emitting diode excites the phosphor, causing the phosphor to emit red, green and blue light rays which, when mixed, are perceived by the human eye as white light. Consequently, white light can also be obtained as a mixture of these light rays.

Designs have been realized in which existing LED's and other electronics are assembled into an integrated housing fixture. In such designs, an LED or plurality of LED's are mounted on a circuit board encapsulated within the housing fixture, and a heat sink is typically mounted to the exterior surface of housing fixture to dissipate heat generated from within the device, the heat being generated by inefficient AC-to DC conversion from with the device. Although devices of this type can generate white light by any of the means described above, their external geometry does not permit direct form, fit, and function replacement of existing incandescent lighting systems currently installed in residential homes. For example, one such prior art device is described in the LED Lighting Fixtures Inc. catalog as part number LR6. The LR6 embodiment includes an encapsulated LED structure with an external heat sink assembly integrated as part of a thermal management system. The necessity of an external heat sink assembly in conjunction with an integrated thermal management system adds significant cost to the device as compared to equivalent light output off-the-shelf incandescent devices. In addition, the incorporation of the external heat sink assembly adds significant weight to the device as well as yields an overall external geometry to the lamp which is cylindrical in nature, not at all similar to the familiar incandescent lamps, which in itself may be an impediment to market acceptance to the average home owner envisioning a direct form, fit, and function swap-out.

Given this, there is a need for a “white light” Led system capable of direct form, fit, and function replacement of existing incandescent systems which can be installed directly by the homeowner without the need of unwanted masonry work and without the additional cost of a licensed technician to perform such an installation.

### SUMMARY OF THE INVENTION

Generally, the present invention is directed to lighting systems, and more particularly to a white light LED-based lighting system configured for direct form, fit, and function replacement of existing incandescent systems.

One embodiment of the present invention describes a lighting device for generating diffuse white light comprising a group of solid state light emitters, electronics to activate the solid state light emitters by converting 120 volt 60 cycles per second alternating current to a steady state voltage, direct current, and an encapsulating housing enclosing the solid state light emitters and the activating electronics.

An alternative embodiment of the present invention describes a lighting device for generating diffuse white light comprising a group of solid state light emitters, electronics to activate the solid state light emitters, wherein the electronics converts and regulates a steady state voltage, direct current input to the electronics, to the solid state light emitters and an encapsulating housing enclosing the solid state light emitters and the activating electronics.

Another embodiment of the present invention describes a lighting device for generating diffuse white light comprising a group of solid state light emitters, electronics to activate the solid state light emitters, wherein the electronics converts and regulates a steady state voltage, direct current input to the electronics, to the solid state light emitters, phosphors which absorb the output of the ultraviolet light emitting diodes and emit visible light; and an encapsulating housing enclosing the solid state light emitters, the phosphors, and the activating electronics.

The above summary of the present invention is not intended to describe each illustrated embodiment or every implementation of the present invention. The figures and the detailed description which follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1A shows a schematic representation of one embodiment of the present invention depicting a white light LED device configured for direct form, fit, and function replacement of existing incandescent systems.

FIG. 1B shows a schematic representation of the prior art incandescent lighting devices highlighting the one-to-one matching external geometry of the prior art versus the embodiment of the present invention as depicted in FIG. 1A.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

In general, the present invention is directed to lighting systems, and more particularly to an LED-based white light lighting system configured for direct form, fit, and function replacement of existing incandescent, halogen, mercury vapor, high pressure sodium, and compact fluorescent systems.

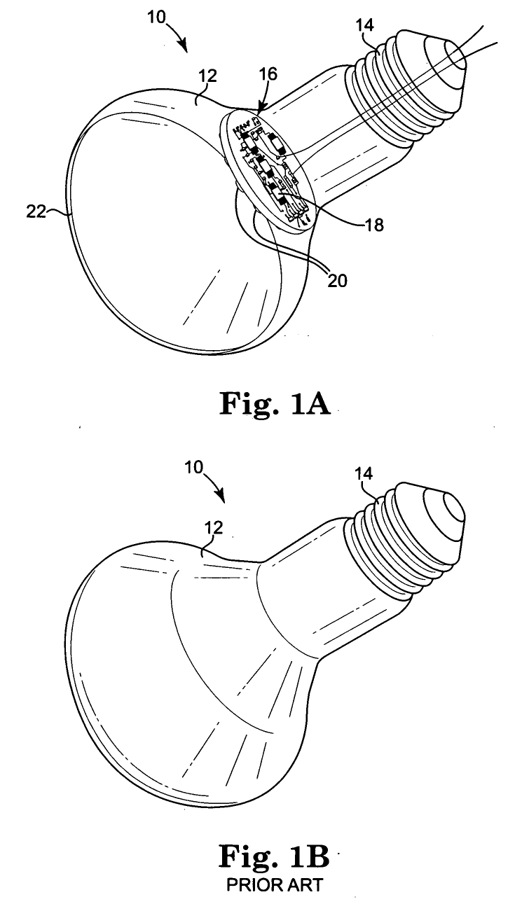

One embodiment of a white light LED device 10 in accordance with the present invention is depicted schematically in FIG. 1A. As shown in FIG. 1A, circuit board 16 may be securely mounted within encapsulating housing 12. Encapsulating housing 12 may consist of the external structure currently in use for standard incandescent lighting devices as depicted in FIG. 1B. Circuit board 16 may have individual electronic and optical components 18 mounted to its surface, which may include any of the LED device structures described below. In one embodiment, circuit board 16 may include the necessary electronic components to convert the standard 120 volt AC (60 Hertz) signal to a direct current (DC) voltage appropriate for the individual LED's mounted on the circuit board. To generate white light, circuit board 16 may have individual red, green, and blue LEDs mounted in sufficiently close proximity such that their respective light outputs are spatially mixed and directed towards diffusing surface 22. Diffusing surface 22 may consist of a frosted or opal like material such that the light emanating from diffusing surface 22 appears uniformly distributed over the surface with no apparent bright spots. Alternatively, circuit board 16 may have one or more ultraviolet LEDs that emit ultraviolet rays which when absorbed by phosphor materials 20 produce red (R), green (G) and blue (B) light rays. In such an “RGB LED lamp”, the red, green and blue light rays which, when mixed, are perceived by the human eye as white light.

In an alternative embodiment of the present invention, mounting threads 14 may securely mate with a housing pre-configured to supply a direct current (DC) voltage to white light LED device 10. In this configuration, circuit board 16 may be configured as a DC-to-DC converter to apply the appropriate DC voltage(s) to the LEDs mounted thereon.

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the present specification. The claims are intended to cover such modifications and devices.

I claim:

1. A lighting device for generating diffuse white light comprising:
a group of solid state light emitters, said group including light emitting diodes;
electronics to activate the solid state light emitters, wherein the electronics converts 120 volt 60 cycles per second alternating current to a steady state voltage direct current; and
an encapsulating housing enclosing the solid state light emitters and the activating electronics.

2. The device of claim 1 wherein the group of solid state emitters comprises a red, green, and blue light emitting diode.

3. The device of claim 1 wherein the encapsulating housing includes a diffusing element.

4. A lighting device for generating diffuse white light comprising:
a group of solid state light emitters, said group including light emitting diodes;
electronics to activate the solid state light emitters, wherein the electronics converts and regulates a steady state voltage, direct current input to the electronics, to the solid state light emitters; and
an encapsulating housing enclosing the solid state light emitters and the activating electronics.

5. A lighting device for generating diffuse white light comprising:
a group of solid state light emitters, said group including ultraviolet light emitting diodes;
electronics to activate the solid state light emitters, wherein the electronics converts and regulates a steady state voltage, direct current input, to the electronics, to the solid state light emitters;
phosphors which absorb the output of the ultraviolet light emitting diodes and emit visible light; and
an encapsulating housing enclosing the solid state light emitters and the activating electronics.

6. The device of claim 5, wherein the phosphors emit respectively red, green, and blue light.
